(19) United States
(12) Patent Application Publication
(10) Pub. No.: US 2010/0203668 A1
(43) Pub. Date: Aug. 12, 2010

(54) METHOD AND APPARATUS FOR THERMALLY CONVERTING METALLIC PRECURSOR LAYERS INTO SEMICONDUCTING LAYERS, AND ALSO SOLAR MODULE

(75) Inventors: Dieter Schmid, Reutlingen (DE); Reinhard Lenz, Blaubeuren (DE); Robert Michael Hartung, Blaubeuren (DE)

Correspondence Address: HESLIN ROTHENBERG FARLEY & MESITI PC, 5 COLUMBIA CIRCLE, ALBANY, NY, 12203, US

(73) Assignee: CENTROTHERM PHOTOVOLTAICS AG, Blaubeuren (DE)

(21) Appl. No.: 12/528,913

(22) PCT Filed: Sep. 11, 2008
(86) PCT No.: PCT/EP2008/007466

§ 371 Date: Apr. 21, 2010

(30) Foreign Application Priority Data
Sep. 11, 2007 (DE) 10 2007 043 051.7
Oct. 1, 2007 (DE) 10 2007 047 098.5
Oct. 1, 2007 (DE) 10 2007 047 099.3
Oct. 8, 2007 (DE) 10 2007 048 204.5

(51) Int. Cl. H01L 31/032; H01L 21/477; H01L 21/10; F27D 3/00

(52) U.S. Cl. 438/84; 438/799; 438/102; 432/246; 257/E21.497; 257/E31.027; 257/E21.07

(57) ABSTRACT

An accelerated and simple-to-realize fast method for thermally converting metallic precursor layers on any desired substrates into semiconducting layers, and also an apparatus suitable for carrying out the method and serving for producing solar modules with high efficiency are provided. The substrates previously prepared at least with a metallic precursor layer are heated in a furnace, which is segmented into a plurality of temperature regions, at a pressure at approximately atmospheric ambient pressure in a plurality of steps in each case to a predetermined temperature up to an end temperature between 400° C. and 600° C. and are converted into semiconducting layers whilst maintaining the end temperature in an atmosphere comprising a mixture of a carrier gas and vaporous chalcogens.

The present invention concerns a method for thermally converting metallic precursor layers on substrates into semiconducting layers, and also an apparatus for carrying out the method and for producing solar modules on substrates.

Such convertible metallic layers, which are also referred to as precursor layers, can contain copper, gallium and indium. The precursor layer can be applied to the substrate, which can be a glass substrate, by means of known technologies, e.g. by sputtering. For the conversion into semiconducting CIGS layers (CIGS: copper indium gallium selenide), so-called chalcogens, that is to say selenium, sulphur, tellurium and compounds thereof among one another or with other substances or mixtures thereof, have to be supplied onto said layers. At room temperature, that is to say around 20° C., said chalcogens assume a solid state of matter and evaporate at temperatures above approximately 350° C. Such glass substrates prepared with a CIGS layer can then be processed further as blanks to form solar modules, this including various contact-connections and, if appropriate, the application of passivations, filter layers, etc.

What is essential for a good efficiency is for the precursor layer to be converted as completely as possible into the CIGS layer with an identical layer thickness over the area.

According to the prior art, methods for thermally converting these prepared precursor layers into semiconducting layers have been disclosed which proceed either under vacuum, or else under atmospheric conditions with the supply of hydrogen-containing gases (EP 0 318 315 A2), but in return are very time-consuming and costly. Typical conversion temperatures are 550° C.

The problem in the vacuum processes is the long conversion time (also called process time). In industrial conversion this leads to problems because long process times are always accompanied by low productivity. One solution would be, on the one hand, to use many machines simultaneously, but this would mean high costs in terms of capital expenditure, or else, on the other hand, to accelerate the processes. However, the prior art does not offer any indications in respect thereof.

EP 0 662 247 B1 has disclosed a method for producing a chalcopyrite semiconductor on a substrate, in which the substrate prepared with metals, such as copper, indium or gallium, is heated in an inert process gas to a process temperature of at least 350° C. at a heating rate of at least 10° C./second. The process temperature is maintained for a time period of 10 seconds to 1 hour, in which the substrate is exposed to sulphur or selenium as a component in excess relative to the components copper, indium or gallium. For this purpose, a covering is situated above the layer construction on the substrate at a distance of less than 5 mm in the sense of an encapsulation. In this case, the partial pressure of sulphur or selenium lies above the partial pressure that would form over a stoichiometrically exact composition of the starting components copper, indium or gallium and sulphur.

The invention is based on the object, then, of providing an accelerated and simple-to-realize fast method for thermally converting metallic layers on any desired substrates into semiconducting layers, and also an apparatus suitable for carrying out the method and serving for producing solar modules with high efficiency.

This is achieved by means of a method of the type mentioned in the introduction by virtue of the fact that the substrates previously prepared at least with a metallic precursor layer are heated in a furnace, which is segmented into different temperature regions, at a pressure at approximately atmospheric ambient pressure in a plurality of steps in each case to a predetermined temperature up to the end temperature between 400° C. and 600° C. and are converted into semiconducting layers whilst maintaining the end temperature in an atmosphere comprising a mixture of a carrier gas and vaporous chalcogens.

The substrates are subsequently cooled to room temperature in at least one step.

In one development of the invention, the substrate is previously prepared with a precursor layer and, above the latter, with a layer of chalcogens prior to introduction into the furnace.

This chalcogen layer is preferably produced by vapour deposition of selenium onto the precursor layer.

The invention is furthermore characterized in that the precursor layers are produced by successive sputtering of copper, indium and gallium.

For this purpose, substrates comprising glass are firstly provided with a first molybdenum layer by sputtering, onto which layer are then sputtered a second layer composed of copper/gallium (CuGA) from a composite target and, finally, a third layer composed of indium from an indium target under a high vacuum.

Furthermore, the heating of the substrates and the conversion of the precursor layers are performed in the absence of oxygen and hydrogen, or with a lowest possible oxygen partial pressure.

After the conclusion of the conversion of the metallic precursor layers into CIGS layers, the substrate can also be cooled in a step-response function.

In a further configuration of the invention, the substrates are transported step by step through the segmented furnace and are in each case heated to a higher temperature in successive segments, the predetermined residence duration in the individual segments being identical.

The residence duration can be 60 seconds.

Furthermore, the substrates are heated in the segments from room temperature, that is to say from an ambient temperature of approximately 20° C., with a decreasing temperature difference up to the end and reaction temperature, the temperature gradient varying from segment to segment in such a way that the heating rate is approximately twice as high in the second section as in the preceding section and the succeeding section, in which the end and reaction temperature is reached.

As an alternative, the heating process can be effected in each section in a step-response function to the respective desired temperature.

The heating can be performed in stages from room temperature to 150° C., 400° C. and 500° C.-600° C., in which case the 550° C. mark must not be exceeded as end temperature.

The heating in the individual sections is performed over in each case an identical time duration, which can be 60 seconds.

The substrates are cooled for example at a cooling rate of 8° C./sec.

Furthermore, the pressure in the process chamber during the conversion process can be set to atmospheric pressure, e.g. to approximately 1000 hPa.

A further configuration of the invention is characterized in that in the segment with the highest target temperature, a mixture of a chalcogen vapour/carrier gas mixture is brought over the surface of the substrate.

The chalcogen vapour/carrier gas mixture can also be supplied from a heated source outside the muffle furnace.

As an alternative, the chalcogen vapour/carrier gas mixture can contain vaporous chalcogen evaporated from the substrate in preceding segments.

In a particular configuration of the invention, the chalcogen vapour/carrier gas mixture is produced from a mixture of chalcogen evaporated from the substrates in a preceding segment and additionally supplied chalcogen vapour from a source.

A mixture of selenium vapour and nitrogen can be used as chalcogen vapour/carrier gas mixture.

The object on which the invention is based is also achieved by means of an apparatus by virtue of the fact that the furnace is divided into a plurality of successive sections having different temperature regions, which are connected to one another by a continuous furnace channel, in which case, between an inlet-side section and an outlet-side section, further sections that can be heated independently of one another are arranged as heating zones and afterwards at least one section is arranged as a cooling zone, that in the furnace channel that connects the sections there is situated a thermally and mechanically low-mass transport device for the step-by-step and simultaneous transport of all the substrates situated in the sections at a high speed from one section to the respective next section, and that the furnace is equipped with inlet- and outlet-side locks.

Furthermore, the inlet-side section can be embodied as lock introduction chamber and the outlet-side section can be embodied as output lock.

In one development of the invention, ambient pressure should prevail in the furnace.

The transport device comprises graphite rollers which are mounted rotatably in the furnace and on which the substrates are guided displaceably in segments longitudinally through the furnace channel, and in that a displaceable and rotatable push rod concomitantly provided with transport lugs with the spacing pitch of the substrates is mounted between the rollers, the transport lugs of which, as viewed in the transport direction, can in each case be brought into engagement with the trailing edge of the substrates, it being possible for the leading edge of the substrates to be brought into engagement with the transport lug of the respective preceding substrate for braking purposes.

The transport lugs can be brought into engagement by rotation of the push rod and, after transport travel has been effected, can be pivoted into a position out of engagement with the substrates.

The residence duration of the substrates in the individual segments is identical and can be 60 seconds, for example.

A further development of the invention is characterized in that the furnace is subdivided into six segments, it being possible for the segments to be temperature-regulated to different, respectively successively higher target temperatures, and a chalcogen vapour/carrier gas mixture with a predetermined concentration being situated in the segment having the highest target temperature.

The target temperatures are graded in the individual segments in such a way that a target temperature of for example 150° C. can be set in the first segment, a target temperature of 400° C. can be set in the following segment, and a target temperature of 550° C. can be set in the next segment, for the substrates.

Furthermore, the segment following the segment having the highest target temperature is connected to an exhaust gas channel for discharging and conditioning excess chalcogen vapour/carrier gas mixture.

Finally, the inlet- and outlet-side locks comprise gas curtains that ensure that the interior of the furnace is sufficiently sealed with respect to oxygen and hydrogen.

Finally, the object on which the invention is based is also achieved by means of a solar module comprising a CIGS layer on a substrate, produced by providing a substrate prepared with a metallic precursor layer, heating the substrate in a plurality of stages to in each case a higher target temperature with different temperature gradients up to the conversion temperature of 550° C. for converting the precursor layer into a CIGS layer with a vaporous chalcogen applied to the precursor layer.

The cooling can be effected for example in a step-response function or at a cooling rate of approximately 8-10° C./second.

The temperature gradient varies from segment to segment in such a way that the heating rate is approximately twice as high in the second section as in the preceding section and the succeeding section, in which the end and reaction temperature is reached.

The method according to the invention achieves a particularly uniform lattice structure of the CIGS layer in association with a higher efficiency of the solar module.

Preferably, vaporous selenium, sulphur, tellurium, compounds thereof among one another or with other substances or mixtures thereof are used as the chalcogen.

Furthermore, the metallic precursor layers contain copper, indium and gallium.

The invention realizes an accelerated method for converting the metallic layers into semiconducting layers.

It has been shown that the processes for converting the metallic layers into semiconducting layers depend both on the temperature and on the ambient pressure.

Although it is generally known that chemical reactions—the conversion of the metallic layers to semiconducting semiconductor layers being such a chemical reaction—are a function of temperature and of pressure, the temperature dependence of the reactions has always been utilized heretofore for the present problem, which can be regarded as an indication that experts have not taken into account, that is to say have overlooked, the variation of the process pressure with regard to the conversion of metallic layers into semiconducting layers.

Advantages of the present method are a faster conversion of metallic layers into semiconducting layers, shorter cycle times in the industrial process and a more cost-effective fabrication since lower capital expenditure arises owing to fewer installations required.

The present invention concerns a novel thermal process for any desired substrates in which metallic layers, which can contain copper, gallium and indium, are converted with selenium and/or sulphur into semiconducting semiconductor layers. The conversion is effected at ambient or atmospheric pressure.

The special feature of the present invention is that rather than working under vacuum, work is performed under atmospheric conditions, or under increased process pressure, whereby the speed of the chemical reactions involved in the conversion is considerably increased.

The invention will be explained in more detail below on the basis of an exemplary embodiment. The associated drawings showing not true to scale:

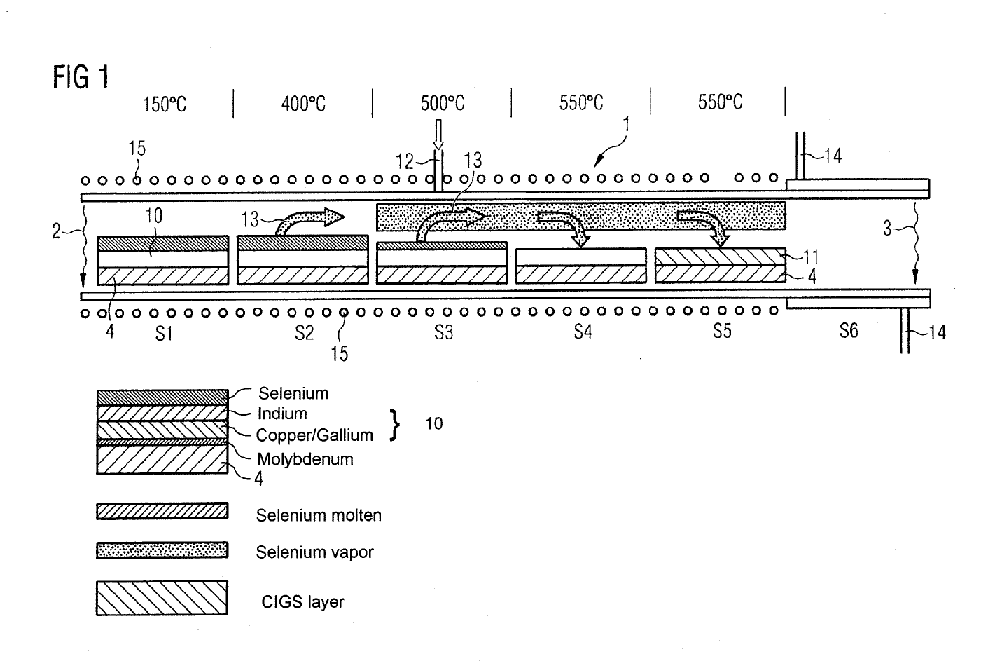

FIG. 1 a schematic illustration of a furnace that is divided into a plurality of segments and is suitable for the step-by-step transport of substrates;

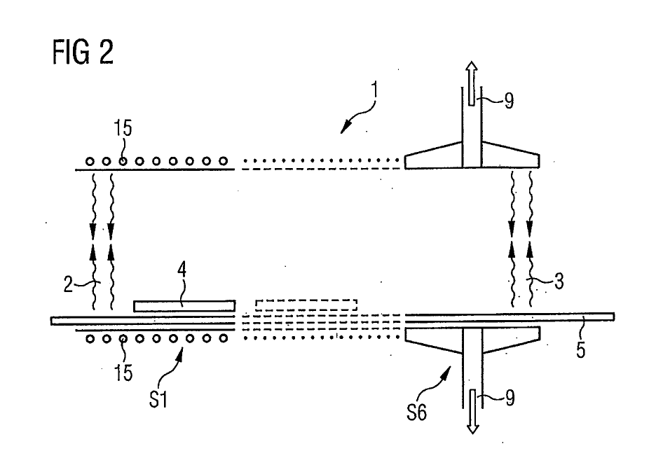

FIG. 2 schematically illustrated details of the furnace according to FIG. 1; and

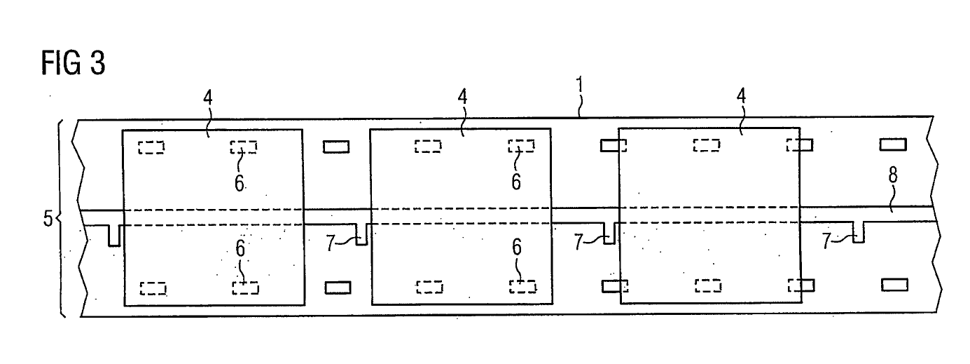

FIG. 3 a schematic plan view of the transport device.

The method according to the invention for thermally converting metallic layers, which can contain copper, gallium or indium, on substrates into semiconducting CIGS layers can be performed per se in any desired furnace 1, e.g. a muffle furnace, which has to meet the following preconditions.

The furnace 1 must comprise heatable or coolable segments S1 . . . Sn, of which the heatable segments S1 . . . Sn must be suitable at least in part for carrying out fast thermal processes.

Furthermore, the furnace 1 must be able to be operated under atmospheric pressure and must be provided with suitable devices for feeding in and discharging gas.

A further important precondition is that care is taken to ensure that the interior of the furnace 1, over the entire length thereof, is constantly kept largely free of oxygen and, if appropriate, also of hydrogen.

The furnace 1 overall is composed of graphite, has a double-walled high-grade steel enclosure and, in accordance with FIG. 1, is subdivided into six successive segments S1 . . . S6.

In order to keep the interior of the furnace 1 free of oxygen and hydrogen, locks 2, 3 in the form of gas curtains composed of an inert gas are provided on the inlet and outlet sides. The oxygen partial pressure in the furnace 1 must in any event be kept extremely low. The locks 2, 3 simultaneously enable substrates 4 to be transported by means of a transport device 5 through the individual segments S1 . . . S6 of the furnace 1 in a continuous method.

The transport device 5 in accordance with FIG. 3 can comprise graphite rollers 6 which are mounted rotatably in the furnace 1 and on which the substrates 4 are pushed in segments longitudinally through the furnace 1. A displaceable and rotatable push rod 8 concomitantly provided with transport lugs 7 with the spacing pitch of the substrates 4 and equipped with a drive (not illustrated) is provided for this purpose.

In order to carry out the transport of all the substrates 4 simultaneously, the transport lugs 7, before each transport travel, are brought into engagement with the substrates 4 by rotation of the push rod 8 upwards and all the substrates 4 are accelerated simultaneously. At the end of each transport travel, the substrates 4 are braked, their leading edge engaging with the transport lug 7 of the respective preceding substrate 4. After the transport travel has been effected, the transport lugs 7 are pivoted away again, whereupon the transport rod 8 is moved back to its starting position again.

The residence duration of the substrates 4 in the individual segments S1 . . . Sn is in each case identical and is 60 seconds, for example.

The gas guiding in the interior of the furnace 1 is configured in such a way that all the gases and vapours supplied to the furnace 1 or arising in the latter are guided from the segment S1 via the following segments S2 . . . Sn to an exhaust gas channel 9. Gas transport in the opposite direction is precluded.

In accordance with FIG. 1, the furnace 1 contains six segments connected to one another via a continuous furnace channel, the segment S1 being temperature-regulated to an internal temperature of approximately 150° C., such that the substrates 4 introduced into the segment 1 are immediately subjected to a first heating process. In this segment, the oxygen and hydrogen entrained into the segment S1 with the transport of the substrates 4 are also removed completely from the segment S1.

In the next segment S2, the substrates are heated to a temperature of 400° C., and to approximately 500° C. in the following segment S3, the temperature gradient varying from segment to segment in such a way that the heating rate is significantly higher, e.g. approximately twice as high, in the second section S2 than in the preceding section S1 and the succeeding section S3, until finally the end and reaction temperature is reached in the section S4 with 550° C. This reaction temperature is maintained in the succeeding section S5.

FIG. 1 illustrates adjacent to the section S5 a section S6, illustrated with an active cooling device 14 in the form of a water cooling. Since, in the event of excessively rapid cooling, thermally induced problems can occur with large-area substrates, it is also possible to insert an intermediate section without heating before the section S6, or to omit the cooling device of the section S6.

As will be explained in more detail below, metallic precursor layers 10 composed of copper, gallium and indium are situated on a molybdenum layer on the previously prepared substrates 4.

For this purpose, substrates 4 comprising glass are firstly provided with a first molybdenum layer by sputtering, onto which layer are then sputtered a second layer composed of copper/gallium (CuGA) from a composite target and, finally, a third layer composed of indium from an indium target under a high vacuum (FIG. 1).

The precursor layers are converted into a semiconducting CIGS layer in the segments S3-S5. This process requires firstly a temperature of 550° C. in the segment S3 S5, and the presence of vaporous chalcogen, e.g. vaporous selenium.

For this purpose, by way of example, the substrates 4 are heated from 400° C. to approximately 500° C. in the segment S3 and to 550° C.-600° C. in the segment S4 and a chalcogen vapour/carrier gas mixture is simultaneously conducted into the segments S3-S5 with sufficient concentration onto the surface of the substrates 4. In this case, the metallic precursor layer is converted abruptly into the desired semiconducting CIGS layer, after which the excess chalcogen vapour/carrier gas mixture is disposed of via the exhaust gas channel 9.

The heating of the segments S1-S5 can be effected externally with the aid of an electrical or other heating 15 illustrated schematically in FIG. 1. Within the furnace 1, the heating is then effected by the heated graphite walls, or in the segment S6, or in further segments the cooling is effected by, for example, cooled graphite walls of the furnace channel.

There are various possibilities for producing the necessary chalcogen concentration in the segments S3-S5. Thus, a chalcogen vapour/carrier gas mixture can be provided from an additional source 12. Another possibility is that the substrates, prior to introduction into the furnace 1, have already been provided with a vapour-deposited chalcogen layer, which then evaporates in the segments S2 and S3 and is conducted by means of the internal gas guiding in the furnace 1 as chalcogen vapour 13, e.g. selenium vapour, into segment S4, and S5, where, if appropriate, residual chalcogen still present finally evaporates and is likewise available there for the conversion process.

The conversion process is referred to as selenium annealing in the case where selenium vapour is used as the chalcogen. As an alternative, the two variants can also be combined with one another. An additional chalcogen vapour/carrier gas mixture can simultaneously be introduced into the segment S2,S3 or S3 if the concentration of the chalcogen evaporated from the substrates is insufficient (FIG. 1).

After a predetermined residence duration in the segment S5, generally 60 seconds, the substrates 4 are pushed into a further segment S6, in which cooling as rapidly as possible is effected by a cooling device 14, whereupon the substrates 4 are then discharged through a lock or pushed into a further segment S and from there discharged through a lock with a temperature of less than 100° C.

It goes without saying that the furnace 1 can also contain more than six segments, and that other temperature stipulations can also be set/chosen in the individual segments, provided that a temperature of 500-600° C. is reached in the segment in which the metallic precursor layer is intended to be converted into the desired CIGS layer. A temperature of 550° C. is a minimum here.

The pressure in the furnace 1 can be at ambient pressure, e.g. at 1000 hPa.

What is crucial for the process control is the interplay between the transport of the substrates 4 through the furnace 1 from segment to segment through the furnace channel. In this case, it must be ensured that enough vaporous chalcogens, e.g. selenium vapour, are present in the furnace atmosphere above the substrates 4 in the segment S4 when the reaction temperature is reached. Only then can an abrupt conversion of copper/gallium and indium of the precursor layer 10 to CIGS take place. This is also achieved by each segment S1-S6 being equipped at any time with one substrate 4 or a plurality of substrates alongside one another, such that this can be designated as quasi-continuous operation of the furnace 1.

### Method and Apparatus for Thermally Converting Metallic Layers into Semiconducting Layers

### LIST OF REFERENCE SYMBOLS

1 Furnace
2 Inlet-side flow lock
3 Outlet-side flow lock
4 Substrate
5 Transport device
6 Graphite roller
7 Transport lug
8 Push rod
9 Exhaust gas channel
10 Precursor layer
11 CIGS layer
12 Source
13 Chalcogen vapour
14 Cooling device
15 Heating

1. Method for thermally converting metallic precursor layers on a substrate into semiconducting layers, wherein the substrates previously prepared at least with a metallic precursor layer are heated in a furnace, which is segmented into a plurality of temperature regions, at a pressure at approximately atmospheric ambient pressure in a plurality of steps in each case to a predetermined temperature up to an end temperature between 400° C. and 600° C. and are converted into semiconducting layers whilst maintaining the end temperature in an atmosphere comprising a mixture of a carrier gas and vaporous chalcogens.

2. Method according to claim 1, wherein the substrates are subsequently cooled to room temperature in at least one step.

3. Method according to claim 1, wherein the substrates is are previously prepared with a precursor layer and, above the precursor layer, with a layer of chalcogens prior to introduction into the furnace.

4. Method according to claim 3, wherein the layer of chalcogens is produced principally by vapour deposition of selenium onto the precursor layer.

5. Method according to claim 1, wherein the precursor layer is produced in a preceding process by successive sputtering of copper, indium and gallium.

6. Method according to claim 5, wherein the substrates comprise glass and are firstly provided with a first molybdenum layer by sputtering, onto the first layer is then sputtered a second layer composed of copper/gallium from a composite target and, finally, a third layer composed of indium from an indium target under a high vacuum.

7. Method according to claim 1, wherein the heating of the substrates and conversion of the precursor layer into a CIGS layer are performed in the absence of oxygen and hydrogen.

8. Method according to claim 1, wherein the cooling of the substrates is effected in a step-response function.

9. Method according to claim 1, wherein the substrates are transported step by step through the segmented furnace and are in each case heated to a higher temperature in successive segments, a predetermined residence duration in individual segments being identical.

10. Method according to claim 9, wherein the residence duration is 60 seconds.

11. Method according to claim 9, wherein the substrates are heated in the segments from room temperature with a decreasing temperature difference up to the end temperature.

12. Method according to claim 11, wherein the substrates are heated in the segments with a temperature gradient that is changed from segment to segment.

13. Method according to claim 11, wherein the substrates are subjected to a heating process in each segment in a step-response function to the respective desired temperature.

14. Method according to claim 1, wherein the heating is effected in stages from room temperature to 150° C., 400° C. and 500° C. to 600° C., or at least 550° C.

15. Method according to claim 1, wherein the heating to the next higher temperature in individual furnace segments is effected over in each case an identical time duration.

16. Method according to claim 1, wherein atmospheric pressure is set, to 1000 hPa in the furnace during a conversion process.

17. Method according to claim 1, wherein in a segment with highest target temperature, a mixture of a chalcogen vapour/carrier gas mixture is brought over a surface of the substrate.

18. Method according to claim 17, wherein the chalcogens vapour/carrier gas mixture is supplied from a source.

19. Method according to claim 17, wherein the chalcogen vapour/carrier gas mixture contains vaporous chalcogen evaporated from a substrate in preceding segments.

20. Method according to claim 17, wherein the chalcogen vapour/carrier gas mixture is produced from a mixture of chalcogen previously evaporated from the substrates and chalcogen vapour additionally supplied from a source.

21. Method according to claim 1, wherein a mixture of selenium vapour and nitrogen is used as chalcogen vapour/carrier gas mixture.

22. Apparatus for carrying out the method of claim 1, in a furnace and with flow locks at an inlet and outlet of a process space, wherein the furnace is divided into a plurality of successive sections having different temperatures, the segments are connected to one another by a continuous furnace channel, between an inlet-side section and an outlet-side section, further sections that can be heated independently of one another are arranged as heating zones and afterwards at least one section is arranged as a cooling zone directly before the outlet-side section, and in the furnace channel that connects the sections there is situated a thermally and mechanically low-mass transport device for step-by-step and simultaneous transport of all the substrates situated in the sections at a high speed from one section to a respective next section, and the furnace is equipped with inlet- and outlet-side locks.

23. Apparatus according to claim 22, wherein the inlet-side section is comprises a lock introduction chamber and the outlet-side section is comprises an output lock.

24. Apparatus according to claim 23, wherein ambient pressure prevails in the furnace.

25. Apparatus according to claim 22, wherein the transport device comprises graphite rollers mounted rotatably in the furnace and on which the substrates are guided displaceably in segments longitudinally through the furnace, and in that a displaceable and rotatable push rod concomitantly provided with transport lugs with a spacing pitch of the substrates is mounted between the rollers, the transport lugs, as viewed in a transport direction, are adapted to be brought into engagement with a trailing edge of the substrates.

26. Apparatus according to claim 25, wherein the transport lugs are adapted to be brought into engagement by rotation of the push rod and, after transport travel has been effected, are adapted to be pivoted into a position out of engagement with the substrates.

27. Apparatus according to claim 22, wherein a residence duration of the substrates in individual segments is identical.

28. Apparatus according to claim 27, wherein the residence duration is 60 seconds.

29. Apparatus according to claim 22, wherein the furnace is subdivided into six segments, second, third and fourth segments being temperature-regulated to different, respectively successively higher target temperatures, and a chalcogen vapour/carrier gas mixture with a predetermined concentration being situated in the fourth segment having the highest target temperature.

30. Apparatus according to claim 29, wherein a desired temperature of 150° C. is set in a first segment, a target temperature of 400° C. is set in the second segment, and a target temperature of approximately 500° C. is set in the third segment and a target temperature of 550° C. is set in the fourth segment and a fifth segment, for the substrates.

31. Apparatus according to claim 29, wherein a segment following the segment having the highest target temperature is connected to an exhaust gas channel for discharging excess chalcogen vapour/carrier gas mixture.

32. Apparatus according to claim 22, wherein the inlet- and outlet-side locks comprise gas curtains.

33. A method for producing a solar module comprising a CIGS layer on a substrate, comprising: providing a substrate prepared with a metallic precursor layer, heating the substrate in a plurality of stages to, in each stage, a higher target temperature with different temperature gradients up to a conversion temperature of 500° C. for converting the precursor layer into a CIGS layer with a vaporous chalcogen applied to the precursor layer, followed by rapid cooling according to a step-response function.

34. Method according to claim 33, wherein vaporous selenium, sulphur, tellurium, compounds thereof among one another or with other substances or mixtures thereof are used as the chalcogen.

35. Method according to claim 33, wherein the metallic precursor layers contains copper, indium and gallium.
